(19) United States
(12) Patent Application Publication
(10) Pub. No.: US 2025/0159834 A1
(43) Pub. Date: May 15, 2025

(54) INTEGRATED CABINET

(71) Applicant: Jinko Energy Storage Technology Co., Ltd., Haining (CN)

(72) Inventors: Shaorong GE, Haining (CN); Guochao CHEN, Haining (CN)

(21) Appl. No.: 18/731,365

(22) Filed: Jun. 3, 2024

(30) Foreign Application Priority Data
Nov. 14, 2023 (CN) 202311520549.9

(51) Int. Cl. H05K 7/14; H02J 9/06

(52) U.S. Cl. CPC H05K 7/1492; H02J 9/062; H05K 7/1489

(57) ABSTRACT

Provided is an integrated cabinet, including a body portion having a first accommodation cavity and a second accommodation cavity, a separator, and a mounting bracket. The separator is configured to separate the first accommodation cavity from the second accommodation cavity. A guide rail is provided at a side wall of the first accommodation cavity. The mounting bracket is mounted in the first accommodation cavity through the guide rail and is movable relative to the body portion. The mounting bracket is configured to mount an uninterruptible power supply. When the mounting bracket moves relative to the body portion, at least part of the mounting bracket and at least part of the UPS are capable of extending out of or retracting into the first accommodation cavity.

### CROSS-REFERENCE TO RELATED APPLICATIONS

The present application claims priority to Chinese Application No. 202311520549.9, filed on Nov. 14, 2023, the content of which is incorporated herein by reference in its entirety.

### TECHNICAL FIELD

The present disclosure relates to the field of energy storage, and in particular, to an integrated cabinet.

### BACKGROUND

An integrated cabinet is a common device in the field of energy storage. An integrated cabinet can be configured to mount a power distribution system. Generally, an uninterruptible power supply (UPS) is directly fixed and mounted in an inner cavity of the integrated cabinet. However, due to a limited internal space of the integrated cabinet, an operating space is small during mounting, disassembly, maintenance, and replacement, making it inconvenient for maintenance personnel to handle the UPS.

### SUMMARY

In view of this, the present disclosure provides an integrated cabinet, aiming to reduce difficulty of maintenance of the UPS.

Some embodiments of the present disclosure provide an integrated cabinet, including: a body portion including a first accommodation cavity and a second accommodation cavity, the first accommodation cavity being configured to mount an alternating current (AC) power distribution system, and the second accommodation cavity being configured to mount a direct current (DC) power distribution system; a separator provided between the first accommodation cavity and the second accommodation cavity; and a mounting bracket provided in the first accommodation cavity and configured to mount an uninterruptible power supply. At least one guide rail is provided at a side wall of the first accommodation cavity, and the mounting bracket is mounted at the at least one guide rail and is movable relative to the body portion along the at least one guide rail, such that at least part of the mounting bracket and at least part of the uninterruptible power supply are capable of extending out of or retracting into the first accommodation cavity.

In some embodiments of the present disclosure, the at least one guide rail includes at least two guide rails provided at a same side of the first accommodation cavity, and the mounting bracket cooperates with the at least two guide rails.

In some embodiments of the present disclosure, the separator is provided with a thermal insulation layer, and/or the separator is made of a thermal insulation material.

In some embodiments of the present disclosure, the mounting bracket includes a main body portion and at least one limiting portion, the limiting portion and the main body portion are connected to each other and an angle is formed between the limiting portion and the main body portion, and the limiting portion extends towards an interior of the first accommodation cavity.

In some embodiments of the present disclosure, the mounting bracket includes at least two limiting portions, and the limiting portions are sequentially arranged in a height direction of the integrated cabinet.

In some embodiments of the present disclosure, the body portion includes at least one first beam, at least one second beam, and at least one third beam. The at least third beam is parallel to a height direction of the integrated cabinet, the at least one first beam and the at least one second beam are perpendicular to the height direction of the integrated cabinet, one or more of the at least one first beam and one or more of the at least one second beam are connected to each other to define a respective frame, the at least one third beam is connected to the frame in the height direction of the integrated cabinet, and two opposite ends of each of the at least one third beam are connected to two frames arranged in an extension direction of the third beam.

In some embodiments of the present disclosure, the body portion includes at least one fourth beam and at least two third beams, each of the at least one fourth beam is located between adjacent third beams, and two opposite ends of each of the at least one fourth beam are connected to the adjacent third beams.

In some embodiments of the present disclosure, one of the at least one fourth beam includes a main body section and two connecting sections, two opposite ends of the main body section are connected to the two connecting sections, an angle is formed between the connecting section and each of the two main body sections, and the main body section and the two connecting sections are jointly define a cavity; and each of the two connecting section is connected to the adjacent third beams.

In some embodiments of the present disclosure, each of the two connecting sections includes a first connecting section and a second connecting section, the first connecting section and the second connecting section are connected to each other and an angle is formed between the first connecting section and the second connecting section, the first connecting section is connected to the main body section, and the second connecting section is connected to the third beam.

In some embodiments of the present disclosure, the at least one guide rail is mounted at the at least one fourth beam.

In some embodiments of the present disclosure, the body portion includes a corner brace including a first connecting portion, a second connecting portion, and a third connecting portion; the first connecting portion and the second connecting portion are connected to each other and an angle is formed between the first connecting portion and the second connecting portion, the third connecting portion is connected to the first connecting portion and/or the second connecting portion, the first connecting portion is connected to the first beam, the second connecting portion is connected to the second beam, and the third connecting portion is connected to the third beam.

In some embodiments of the present disclosure, the first connecting portion is detachably connected to the first beam, the second connecting portion is detachably connected to the second beam, and the third connecting portion is detachably connected to the third beam.

In some embodiments of the present disclosure, the corner brace includes a connecting plate and a connecting member; at least one of the first connecting portion, the second connecting portion, or the third connecting portion is connected to the connecting plate; and the connecting member is arranged at the connecting plate.

In some embodiments of the present disclosure, the integrated cabinet includes a base, and the base is located below the body portion in a height direction of the integrated cabinet.

The present disclosure provides an integrated cabinet. The integrated cabinet includes a body portion having a first accommodation cavity and a second accommodation cavity, a separator, and a mounting bracket. The separator is located between the first accommodation cavity and the second accommodation cavity. A guide rail is provided at a side wall of the first accommodation cavity. The mounting bracket is mounted in the first accommodation cavity through the guide rail and is movable relative to the body portion. The mounting bracket is configured to mount an UPS. When the mounting bracket moves relative to the body portion, at least part of the mounting bracket and at least part of the UPS are capable of extending out of or retracting into the first accommodation cavity. Through such a design, it is easy to put in and take out the UPS, and operations such as mounting, maintenance, and replacement can be performed outside the first accommodation cavity, thereby increasing an operating space, reducing operational difficulty, and being more in accordance with an actual use requirement.

### BRIEF DESCRIPTION OF DRAWINGS

In order to more clearly illustrate the technical solutions in embodiments of the present disclosure, the accompanying drawings to be used in the description of the embodiments will be briefly introduced below. It is apparent that the accompanying drawings in the following description are only some embodiments of the present disclosure, and other drawings can be obtained by those of ordinary skill in the art from the provided drawings without creative efforts.

FIG. 1 is a schematic diagram of an integrated cabinet according to some embodiments of the present disclosure;

FIG. 2 is a schematic diagram of a framework of an integrated cabinet according to some embodiments of the present disclosure;

FIG. 3 is a partial enlarged view of Position I in FIG. 2;

FIG. 4 is a partial schematic diagram of an integrated cabinet according to some embodiments of the present disclosure;

FIG. 5 is a schematic diagram of a mounting bracket according to some embodiments of the present disclosure;

FIG. 6 is a schematic diagram of a fourth beam according to some embodiments of the present disclosure; and

FIG. 7 is a schematic diagram of a corner brace according to some embodiments of the present disclosure.

### REFERENCE SIGNS

1: body portion;
   11: first accommodation cavity;
      111: guide rail;
   12: second accommodation cavity;
   13: first beam;
   14: second beam;
   15: third beam;
   16: fourth beam;
      161: main body section;
      162: connecting section;
         162a: first connecting section;
         162b: second connecting section;
      163: cavity;
   17: corner brace;
      171: first connecting portion;
      172: second connecting portion;
      173: third connecting portion;
      174: connecting plate;
      175: connecting member;
2: separator;
3: mounting bracket;
   31: limiting portion;
4: base;
5: uninterruptible power supply (UPS).

### DESCRIPTION OF EMBODIMENTS

In order to better illustrate the technical solutions of the present disclosure, the embodiments of the present disclosure will be described in detail below with reference to the accompanying drawings.

It should be noted that the described embodiments are only some of, rather than all of the embodiments of the present disclosure. Based on the embodiments in the present disclosure, all other embodiments obtained by those of ordinary skill in the art without making creative efforts shall fall within the protection scope of the present disclosure.

The terms used in the embodiments of the present disclosure are for the purpose of describing embodiments only and are not intended to limit the present disclosure. As used in the embodiments of the present disclosure and the appended claims, the singular forms “a,” “an”, and “the” are intended to include the plural forms as well, unless the context clearly dictates otherwise.

It should be understood that the term “and/or” used herein is merely an association relationship describing associated objects, indicating that there may be three relationships. For example, A and/or B may indicate that there are three cases of: A alone, A and B together, and B alone. In addition, the character “/” herein generally indicates that the related objects before and after the character form an “or” relationship.

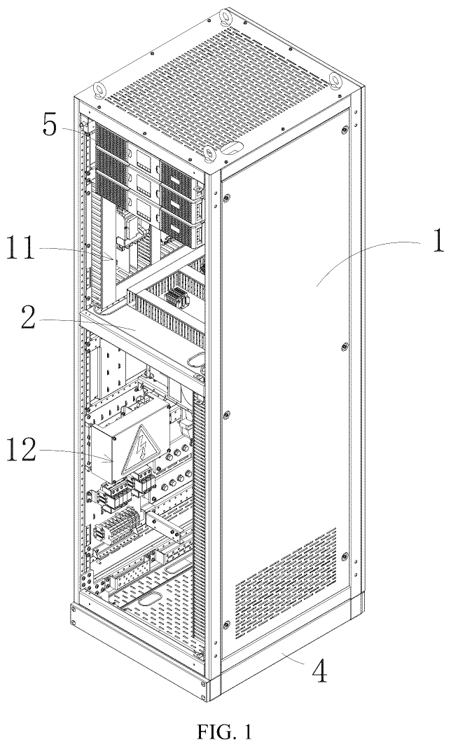

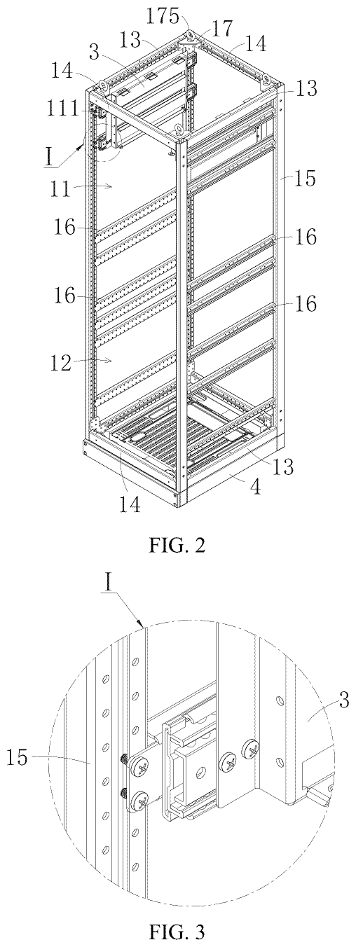

As shown in FIG. 1, some embodiments of the present disclosure provide an integrated cabinet. The integrated cabinet includes a body portion 1, a separator 2, and a mounting bracket 3. The body portion 1 includes a first accommodation cavity 11 and a second accommodation cavity 12, and the separator 2 is located between the first accommodation cavity 11 and the second accommodation cavity 12 to separate the first accommodation cavity 11 from the second accommodation cavity 12. The first accommodation cavity 11 may be configured to mount an AC power distribution system, and the second accommodation cavity 12 may be configured to mount a DC power distribution system. The mounting bracket 3 is located in the first accommodation cavity 11 and is configured to mount an uninterruptible power supply (UPS) 5. As shown in FIG. 2 and FIG. 3, a guide rail 111 is provided at a side wall of the first accommodation cavity 11, and the mounting bracket 3 is mounted at the guide rail 111 and is movable along the guide rail 111 relative to the body portion 1. The UPS 5 is mounted in the first accommodation cavity 11 by means of the mounting bracket 3. When the mounting bracket 3 moves along the guide rail 111, at least part thereof can extend out of or retract into the first accommodation cavity 11. The UPS 5 can move along with the mounting bracket 3 so that at least part of the UPS 5 can extend out of or retract into the first accommodation cavity 11 along with the mounting bracket 3.

By providing the guide rail 111 on the side wall of the first accommodation cavity 11, the mounting bracket 3 and the UPS 5 can move relative to the body portion 1, thereby enabling at least part of the mounting bracket 3 and at least part of the UPS 5 to extend out of or retract into the first accommodation cavity 11. Compared with the solution of directly fixing the mounting bracket 3 and the UPS 5 at the side wall of the first accommodation cavity 11, in the solution provided in some embodiments of the present disclosure, it is easy to put in and take out the UPS 5 through the addition of the guide rail 111, the mounting bracket 3 can be pulled out through the guide rail 111 during mounting, maintenance, and replacement of the UPS 5, and after completion of operations such as mounting, maintenance, and replacement of the UPS 5, the mounting bracket 3 and the UPS 5 can be then put in the first accommodation cavity 11 along the guide rail 111. Through such a design, the operations such as mounting, maintenance, and replacement can be performed outside the first accommodation cavity 11, thereby increasing an operating space, reducing operational difficulty, and being more in accordance with an actual use requirement.

The first accommodation cavity 11 and the second accommodation cavity 12 are respectively configured to mount the AC power distribution system and the DC power distribution system and are separated by the separator 2, thereby reducing a possibility of mutual interference between the AC power distribution system and the DC power distribution system during operation, and thus helping improve operational stability of the integrated cabinet and being more in accordance with an actual use requirement.

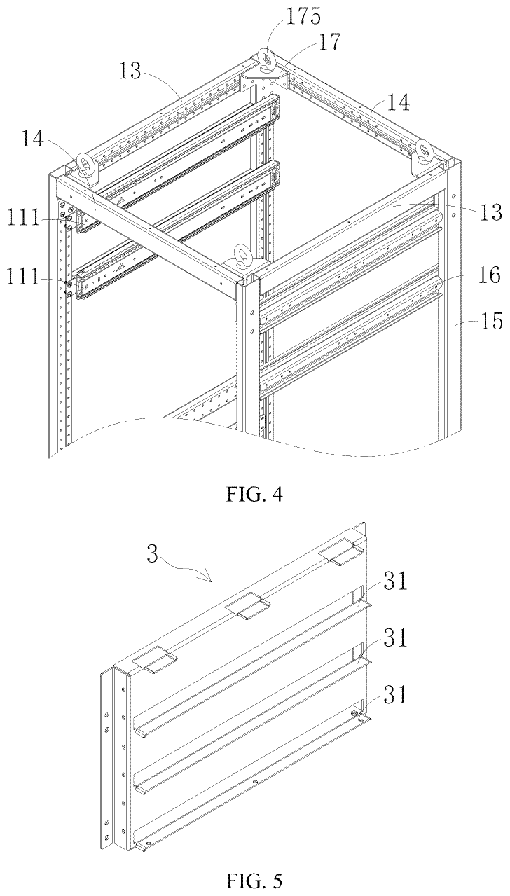

As shown in FIG. 4, in some embodiments, at least two guide rails 111 are provided at a side wall at a same side of the accommodation cavity, and one mounting bracket 3 cooperate with at least two guide rails 111.

The cooperation of the mounting bracket 3 with at least two guide rails 111 can help improve stability of movement of the mounting bracket 3 and be more in accordance with an actual use requirement.

In some embodiments, the separator 2 is provided with a thermal insulation layer, and/or the separator 2 is made of a thermal insulation material.

The separator 2 may be made of a thermal insulation material such as gypsum or foam, or the separator 2 may be coated with a thermal insulation coating or provided with a thermal insulation member, or the like, so that the separator 2 can separate the first accommodation cavity 11 from the second accommodation cavity 12 and can also perform thermal insulation to reduce a possibility of interaction between heat generated by components in the first accommodation cavity 11 and components in the second accommodation cavity 12 during operation. Therefore, it can reduce a possibility of an influence on normal operation of internal components caused by a rising temperature of the accommodation cavity due to heat exchange between the first accommodation cavity 11 and the second accommodation cavity 12, so that it can be more in accordance with an actual use requirement.

As shown in FIG. 5, in some embodiments, the mounting bracket 3 includes a main body portion and at least one limiting portion 31, and the limiting portion 31 is connected to the main body portion and an angle is formed between the limiting portion 31 and the main body portion. The limiting portion 31 extends towards an interior of the first accommodation cavity 11.

The limiting portion 31 can be configured to limit a position of the UPS 5 in a height direction of the integrated cabinet.

In some embodiments, an extension direction of the limiting portion 31 is perpendicular to the height direction of the integrated cabinet.

Through such a design, a contact area between the limiting portion 31 and the UPS 5 can be increased, facilitating the limiting of the UPS 5, thereby improving accuracy of mounting of the UPS 5 and being more in accordance with an actual use requirement.

As shown in FIG. 5, in some embodiments, the mounting bracket 3 includes at least two limiting portions 31, which are sequentially arranged along a height direction of the integrated cabinet.

Through such a design, the mounting bracket 3 can limit positions of a plurality of UPSs 5, and an upper side and a lower side of the UPS 5 located between adjacent limiting portions 31 can be limited by the limiting portions 31, thereby helping improve accuracy of a mounting position of the UPS 5 and being more in accordance with an actual use requirement.

As shown in FIG. 2 and FIG. 4, in some embodiments, the body portion 1 includes a first beam 13, a second beam 14, and a third beam 15. The first beam 13 and the second beam 14 are arranged perpendicular to the height direction of the integrated cabinet, and the third beam 15 is arranged parallel to the height direction of the integrated cabinet. The first beam 13 and the second beam 14 are connected to each other to define a frame, the third beam 15 is connected to the frame defined by the first beam 13 and the second beam 14, and two opposite ends of the third beam 15 in an extension direction of the third beam 15 are connected to the corresponding frames.

The first beam 13 and the second beam 14 may serve as cross beams of the integrated cabinet, the third beam 15 may serve as a vertical beam of the integrated cabinet. The first beam 13 and the second beam 14 may be perpendicular to each other. For example, the first beam 13 may extend along a length direction of the integrated cabinet, and the second beam 14 may extend along a width direction of the integrated cabinet. The frame may include two first beams 13 and two second beams 14, and the frame may have a rectangular shape. Through such a design, the first beam 13, the second beam 14, and the third beam 15 may be used to form a framework of the integrated cabinet, to enhance structural strength of the integrated cabinet.

As shown in FIG. 2, in some embodiments, the body portion 1 includes at least one fourth beam 16 and at least two third beams 15, two opposite ends of each of the third beams 15 are connected to the frame, and two opposite sides of the integrated cabinet in the height direction of the integrated cabinet are each provided with the frame. The fourth beam 16 is provided between two adjacent third beams 15, and two opposite ends of the fourth beam 16 are connected to the two adjacent third beams 15.

By providing the fourth beam 16, the body portion 1 can be strengthened, thereby improving structural strength of the body portion 1 and reducing a possibility of deformation of the body portion 1, and thus improving overall structural strength of the integrated cabinet and being more in accordance with an actual use requirement.

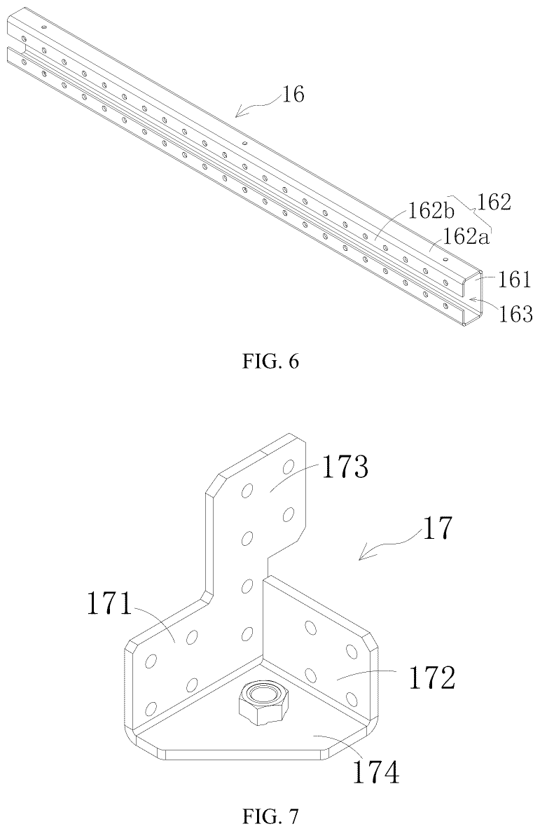

As shown in FIG. 6, in some embodiments, the fourth beam 16 includes a main body section 161 and a connecting section 162. Each of two opposite ends of the main body section 161 is connected to the connecting section 162, and an angle is formed between the connecting section 162 and the main body section 161. The main body section 161 and the connecting section 162 define a cavity 163. A cross section of the fourth beam 16 may be in a “C” shape. A same connecting section 162 is connected to adjacent third beams 15.

Through such a design, structural strength of the fourth beam 16 can be improved, thereby improving a reinforcing effect of the fourth beam 16 on the body portion 1, and thus helping improve the overall structural strength of the integrated cabinet. At the same time, the fourth beam may have a hollow structure, which plays a buffering role and can also achieve weight reduction, thereby helping reduce an overall weight of the integrated cabinet and being more in accordance with an actual use requirement.

As shown in FIG. 2, in some embodiments, the body portion 1 may include four first beams 13, four second beams 14, and four third beams 15. Two first beams 13 and two second beams 14 may be used to form a rectangular frame, and two opposite ends of each of the four third beams 15 are connected to the frame to form an approximately cuboid framework. At least one fourth beam 16 is provided between two adjacent third beams 15. The fourth beam 16 is used for reinforcement. A number of the fourth beam 16 may be arranged according to an actual requirement. In order to further improve the structural strength of the body portion 1, two, three, four, or more fourth beams 16 may be provided between two adjacent third beams 15.

The body portion 1 may further include a baffle, a cabinet door, and the like. The baffle and the cabinet door may be connected to the corresponding first beam 13, second beam 14, and third beam 15 to form a cabinet body.

As shown in FIG. 6, in some embodiments, the connecting section 162 includes a first connecting section 162a and a second connecting section 162b, the first connecting section 162a and the second connecting section 162b are connected to each other and an angle is formed between the first connecting section 162a and the second connecting section 162b. The first connecting section 162a is connected to the main body section 161, and the second connecting section 162b is connected to the third beam 15.

Through such a design, the connection between the fourth beam 16 and the third beam 15 can be facilitated, and the angle between the first connecting section 162a and the second connecting section 162b enables the first connecting section 162a to better fit the third beam 15, thereby helping increase a contact area between the first connecting section 162a and the third beam 15 and thus improving connection stability of the second beam 14 therebetween.

In some embodiments, the third beam 15 has a first connecting surface, the first connecting section 162a has a second connecting surface, the second connecting surface is located on a side of the first connecting section 162a facing the third beam 15, and the first connecting surface is parallel to the second connecting surface. Through such a design, the contact area between the third beam 15 and the first connecting section 162a can be further increased, thereby further improving stability of the connection between the two, and thus helping improve the overall structural strength of the integrated cabinet.

In some embodiments, the guide rail 111 is mounted at the fourth beam 16.

Through such a design, the guide rail 111 can be easily positioned during mounting, thereby improving relative position accuracy of the guide rail 111.

As shown in FIG. 4 and FIG. 7, in some embodiments, the body portion 1 may further include a corner brace 17, the corner brace 17 may include a first connecting portion 171, a second connecting portion 172, and a third connecting portion 173. The first connecting portion 171 is connected to the second connecting portion 172, and an angle is formed between the first connecting portion 171 and the second connecting portion 172. The third connecting portion 173 is connected to the first connecting portion 171 and/or the second connecting portion 172. The first connecting portion 171 is connected to the first beam 13, the second connecting portion 172 is connected to the second beam 14, and the third connecting portion 173 is connected to the third beam 15.

Through such a design, the first beam 13, the second beam 14, and the third beam 15 can be easily connected, so that the first beam 13, the second beam 14, and the third beam 15 can be connected together through the corner brace 17 and then can be combined to form the framework of the integrated cabinet.

In some embodiments, the first beam 13 is detachably connected to the first connecting portion 171, the second beam 14 is detachably connected to the second connecting portion 172, and the third beam 15 is detachably connected to the third connecting portion 173.

Through such a design, the body portion 1 of the integrated cabinet can be easily assembled and disassembled, thereby reducing operational difficulty. The assembling can be performed after being transported to a designated position. Transporting the first beam 13, the second beam 14, the third beam 15, and other structures in the form of components can save space and facilitate transportation.

As shown in FIG. 7, in some embodiments, the corner brace 17 includes a connecting plate 174 and a connecting member 175, at least one of the first connecting portion 171, the second connecting portion 172, and the third connecting portion 173 is connected to the connecting plate 174, and the connecting member 175 is arranged on the connecting plate 174.

The connecting member 175 may be a component such as a lifting ring, and configured to cooperate with a device that transfers the integrated cabinet. By integrating the connecting member 175 into the corner brace 17, the structure of the integrated cabinet can be simplified, and the problem of separate arrangement of a lifting ring mounting portion in the integrated cabinet can be prevented, thereby reducing a volume of the integrated cabinet, saving space and reducing costs, and being more in accordance with an actual use requirement.

The connecting member 175 may be mounted to the connecting plate 174 of the corner brace 17 through a threaded connection.

As shown in FIG. 7, in some embodiments, the first connecting portion 171 and the second connecting portion 172 are perpendicular to each other, the third connecting portion 173 is connected to the first connecting portion 171, and the third connecting portion 173 and the first connecting portion 171 may be located on a same plane. The connecting plate 174 is connected to the first connecting portion 171 and the second connecting portion 172. That is, the connecting plate 174 may be perpendicular to the first connecting portion 171 and the second connecting portion 172 at the same time. The connecting member 175 may be located at a side of the connecting plate 174 away from the first connecting portion 171 and the second connecting portion 172.

Through such a design, the first connecting portion 171, the second connecting portion 172, and the connecting plate 174 can define a structure similar to a triangular pyramid, thereby improving structural strength of the corner brace 17 and being more in accordance with an actual use requirement.

As shown in FIG. 1, in some embodiments, the integrated cabinet may include a base 4, and along the height direction of the integrated cabinet, the base 4 is located below the body portion 1 to raise the body portion 1.

Through the arrangement of the base 4, the body portion 1 may be at a distance from the ground when placed, so that the body portion 1 can be raised, thereby helping improve a moisture-proof capability of the integrated cabinet. Moreover, by raising the body portion 1, an arrangement of a cable at the bottom of the body portion 1 can be facilitated, thereby being more in accordance with an actual use requirement.

In some embodiments, the base 4 may be welded/soldered to the first beam 13 and the second beam 14, and/or the base 4 may be detachably connected to the corner brace 17.

In some embodiments, the base 4 may be provided with a forklift hole, and the integrated cabinet can be transported by the forklift when transporting the integrated cabinet. Arranging the forklift hole at the base 4 can facilitate the forklift to transport the integrated cabinet, and can also reduce a possibility of mutual interference between the forklift and the body portion 1 during transportation, thereby being more in accordance with an actual use requirement.

Some embodiments of the present disclosure provide an integrated cabinet. The integrated cabinet includes a body portion 1 having a first accommodation cavity 11 and a second accommodation cavity 12, a separator 2, and a mounting bracket 3. The separator 2 is configured to separate the first accommodation cavity 11 from the second accommodation cavity 12. A guide rail 111 is provided at a side wall of the first accommodation cavity 11. The mounting bracket 3 is mounted in the first accommodation cavity 11 through the guide rail 111 and is movable relative to the body portion 1. The mounting bracket 3 is configured to mount an UPS 5. When the mounting bracket 3 moves relative to the body portion 1, at least part of the mounting bracket 3 and at least part of the UPS 5 can extend out of or retract into the first accommodation cavity 11. Through such a design, it is easy to put in and take out the UPS 5, and operations such as mounting, maintenance, and replacement can be performed outside the first accommodation cavity 11, thereby increasing an operating space, reducing operational difficulty, and being more in accordance with an actual use requirement.

Same and similar parts in the embodiments may be referred to one another. In particular, the apparatus embodiments and the terminal embodiments are basically similar to the method embodiments, so the description thereof is relatively simple. Related parts can be obtained with reference to the corresponding description in the method embodiments.

What is claimed is:

1. An integrated cabinet, comprising:
a body portion (1) comprising a first accommodation cavity (11) and a second accommodation cavity (12), wherein the first accommodation cavity (11) is configured to mount an alternating current (AC) power distribution system, and the second accommodation cavity (12) is configured to mount a direct current (DC) power distribution system;
a separator (2) provided between the first accommodation cavity (11) and the second accommodation cavity (12); and
a mounting bracket (3) provided in the first accommodation cavity (11) and configured to mount an uninterruptible power supply (5),
wherein at least one guide rail (111) is provided at a side wall of the first accommodation cavity (11), and the mounting bracket (3) is mounted at the at least one guide rail (111) and is movable relative to the body portion (1) along the at least one guide rail (111), such that at least part of the mounting bracket (3) and at least part of the uninterruptible power supply (5) are capable of extending out of or retracting into the first accommodation cavity (11).

2. The integrated cabinet according to claim 1, wherein the at least one guide rail (111) comprises at least two guide rails (111) provided at a same side of the first accommodation cavity (11), and the mounting bracket (3) cooperates with the at least two guide rails (111).

3. The integrated cabinet according to claim 1, wherein the separator (2) is provided with a thermal insulation layer.

4. The integrated cabinet according to claim 1, wherein the separator (2) is made of a thermal insulation material.

5. The integrated cabinet according to claim 1, wherein the mounting bracket (3) comprises a main body portion and at least one limiting portion (31), the limiting portion (31) and the main body portion are connected to each other and an angle is formed between the limiting portion (31) and the main body portion, and the limiting portion (31) extends towards an interior of the first accommodation cavity (11).

6. The integrated cabinet according to claim 5, wherein the extending direction of the limiting portion (31) is perpendicular to a height direction of the integrated cabinet.

7. The integrated cabinet according to claim 5, wherein the mounting bracket (3) comprises at least two limiting portions (31), and the limiting portions (31) are sequentially arranged in a height direction of the integrated cabinet.

8. The integrated cabinet according to claim 1, wherein the body portion (1) comprises at least one first beam (13), at least one second beam (14), and at least one third beam (15), wherein the at least third beam (15) is parallel to a height direction of the integrated cabinet, the at least one first beam (13) and the at least one second beam (14) are perpendicular to the height direction of the integrated cabinet, one or more of the at least one first beam (13) and one or more of the at least one second beam (14) are connected to each other to define a respective frame, the at least one third beam (15) is connected to the frame in the height direction of the integrated cabinet, and two opposite ends of each of the at least one third beam (15) are connected to two frames arranged in an extension direction of the third beam (15).

9. The integrated cabinet according to claim 8, the frame defined by one or more of the at least one first beam (13) and one or more of the at least one second beam (14) has a rectangular shape.

10. The integrated cabinet according to claim 8, wherein the body portion (1) comprises at least one fourth beam (16) and at least two third beams (15), each of the at least one fourth beam (16) is located between adjacent third beams (15), and two opposite ends of each of the at least one fourth beam (16) are connected to the adjacent third beams (15).

11. The integrated cabinet according to claim 10, wherein at least two fourth beams (16) are provided between two adjacent third beams (15).

12. The integrated cabinet according to claim 10, wherein one of the at least one fourth beam (16) comprises a main body section (161) and two connecting sections (162), two opposite ends of the main body section (161) are connected to the two connecting sections (162), an angle is formed between the connecting section (162) and each of the two main body sections (161), and the main body section (161) and the two connecting sections (162) jointly define a cavity (163); an each of the two connecting section (162) is connected to the adjacent third beams (15).

13. The integrated cabinet according to claim 12, wherein a cross section of the fourth beam (16) is in a “C” shape.

14. The integrated cabinet according to claim 12, wherein each of the two connecting sections (162) comprises a first connecting section (162a) and a second connecting section (162b), the first connecting section (162a) and the second connecting section (162b) are connected to each other and an angle is formed between the first connecting section (162a) and the second connecting section (162b), the first connecting section (162a) is connected to the main body section (161), and the second connecting section (162b) is connected to the third beam (15).

15. The integrated cabinet according to claim 14, wherein the third beam (15) has a first connecting surface, the first connecting section (162a) has a second connecting surface, the second connecting surface is located on a side of the first connecting section (162a) facing the third beam (15), and the first connecting surface is parallel to the second connecting surface.

16. The integrated cabinet according to claim 10, wherein the at least one guide rail (111) is mounted at the at least one fourth beam (16).

17. The integrated cabinet according to claim 8, wherein the body portion (1) comprises a corner brace (17) comprising a first connecting portion (171), a second connecting portion (172), and a third connecting portion (173); the first connecting portion (171) and the second connecting portion (172) are connected to each other and an angle is formed between the first connecting portion (171) and the second connecting portion (172), the third connecting portion (173) is connected to the first connecting portion (171) and/or the second connecting portion (172), the first connecting portion (171) is connected to the first beam (13), the second connecting portion (172) is connected to the second beam (14), and the third connecting portion (173) is connected to the third beam (15).

18. The integrated cabinet according to claim 17, wherein the first connecting portion (171) is detachably connected to the first beam (13), the second connecting portion (172) is detachably connected to the second beam (14), and the third connecting portion (173) is detachably connected to the third beam (15).

19. The integrated cabinet according to claim 17, wherein the corner brace (17) comprises a connecting plate (174) and a connecting member (175); at least one of the first connecting portion (171), the second connecting portion (172), or the third connecting portion (173) is connected to the connecting plate (174); and the connecting member (175) is arranged at the connecting plate (174).

20. The integrated cabinet according to claim 1, comprising a base (4), wherein the base (4) is located below the body portion (1) in a height direction of the integrated cabinet.
